(19) United States
(12) Patent Application Publication
(10) Pub. No.: US 2005/0211668 A1
(43) Pub. Date: Sep. 29, 2005

(54) Methods of processing a substrate with minimal scalloping

(75) Inventor: Tamarak Pandhumsoporn, Fremont, CA (US)

Correspondence Address: IPSG, P.C., P.O. BOX 700640, SAN JOSE, CA, 95170-0640, US

(73) Assignee: Lam Research Corporation, Fremont, CA (US)

(21) Appl. No.: 10/882,036

(22) Filed: Jun. 29, 2004

Related U.S. Application Data
(60) Provisional application No. 60/556,707, filed on Mar. 26, 2004.

(51) Int. Cl. H01L 21/302; B44C 1/22

(52) U.S. Cl. 216/59; 216/41; 216/67; 438/706

(57) ABSTRACT

The present invention provides methods of processing a substrate with minimal scalloping. By processing substrates with minimal scalloping, feature tolerance and quality may be improved. An embodiment of the present invention provides a method for etching a feature in a layer through an etching mask by alternating steps of polymer deposition and substrate etching in any order. In order to achieve the benefits described herein, process gas pressures between process steps may be substantially equivalent. In some embodiments a continuous plasma stream may be maintained throughout substrate processing. In still other embodiments, process gases may be controlled by a single mass flow control valve so that process gases may be switched to within less than 250 milliseconds.

### BACKGROUND OF THE INVENTION

The present invention relates to methods and apparatus of obtaining a feature on a semiconductor wafer by etching through structures defined by a mask using plasma under controlled process conditions. More particularly, the invention relates to methods and apparatus for reducing scalloping during plasma etching.

A variety of methods for the anisotropic etching of silicon and polysilicon film materials have been disclosed including: difference, reactive ion etch (RIE), triodes, microwave, inductive coupling plasma sources, etc. Generally, etching is a process by which a desired pattern or feature is transferred to a substrate through selective removal of portions of the substrate. Substrate etching may be accomplished by either chemical or physical etching. Plasma etching is accomplished by using a chemically reactive and/or physically energetic species with electrically charged particles. That is, ions and other particles are produced in a vacuum chamber in combination with a gas mixture of single gases or multiple gases. The positively charged ions or other electrically charged particles may be accelerated toward the substrate by applying bias voltages to etch the substrate.

Substrate etching can exhibit either anisotropic or isotropic characteristics on a substrate. Directional ions enhanced with high-energy current tent along with polymer sidewall protection tend to provide a more anisotropic etching profile on the substrate. Furthermore, the gas ionization in plasma state generally contains non-trivial amounts of incident ions present during plasma etching. Incident ions accounts for isotropic etching, which is characterized by etching in all directions more or less equally.

A mask, representing the negative image of the desired pattern, covers the substrate to delimit the area removed by etching. Masking may be accomplished by any method well known in the art including for example: hard masking, resist masking, or oxide masking. Hard masks may comprise any of a number of materials including, for example, dielectric materials such as silicon dioxide, silicon nitride, and silicon carbide, and metallic materials such as aluminum metal. Positive and negative resist masks may be utilized for etching crystalline silicon, polysilicon, and amorphous silicon. Notably, mask erosion properties must be considered when selecting appropriate etching gases to achieve minimum mask erosion while also achieving maximum substrate etching.

Example etching profiles are considered in FIGS. 1A-1C. FIGS. 1A-1C illustrate cross-sections of a conventional substrate etch having a mask material patterned on the substrate exhibiting isotropic and anisotropic etch properties. Referring to FIG. 1A, a substrate 108 having a mask 104 is shown in cross-section. Figures are for illustrative purposes only and are not intended to be scale representations. In this example any number of substrate materials well known in the art and any number of mask materials well known in the art may be utilized. FIG. 1B illustrates an example intermediate step during an etch process. In this example, the substrate 108 had been etched or partially etched. Directed ions 112 account for the majority of the etch pattern and direction. Typically, directed ions 112 etch the substrate in a direction substantially perpendicular to the substrate. As noted above, this property is generally known as anisotropic etching. Further, as noted above, incident ions 116 may be present in ionization gases in non-trivial concentrations, which account for some isotropic etching. These incident ions strike the substrate in non-perpendicular directions leading to sidewall erosion as demonstrated by the scalloped profile 118. FIG. 1C illustrates an example profile of a portion of an etched substrate using conventional methods after the mask layer has been stripped from the substrate.

In other examples, low photo resist mask selectivity with chlorine gases has been observed in the silicon etching. Mask erosion rates generally depend on several factors including: gas type, reactivity of ions and other etchant particles, temperatures, and operating pressure. Gas mixtures containing fluorinated hydrogen may reduce mask erosion as well as provide better sidewall protection. Polymer or passivation layer deposition resulting in sidewall protection has been studied using etchant gas SF₆ with oxygen or nitrogen with some limitations. Dielectric layers formed by SiOₓ or SiN_{X} layers generated on the surface are generally only atomic-layer thick and do not cover well in all areas. This limitation makes the process more difficult to control. And while chlorine, bromine, and iodine type gases generally provide lower etch rates when compared to fluorine gases without hydrogen, those gases also exhibit less lateral etching than fluorine gases. Mixtures of these gases have been tested and have provided varying degrees of effective anistropic etching.

Scalloping along the etch profile sidewalls is a phenomenon that has been extensively studied. With scalloping, the sidewalls of the etched feature assume a scalloped appearance instead of being relatively smooth and/or straight. Such scalloping tends to negatively affect the electrical and/or physical characteristics of the resultant device. Among other benefits, embodiments of the invention described below address this scalloping issue.

In view of the foregoing, methods of processing a substrate with minimal scalloping are presented herein.

### SUMMARY OF THE INVENTION

The present invention provides methods of processing a substrate with minimal scalloping. By processing substrates with minimal scalloping, feature tolerance and quality may be improved.

One embodiment of the present invention provides a method for etching a feature in a layer through an etching mask where the method includes the steps of providing a polymer deposition gas at a first pressure; forming a first plasma from the polymer deposition gas; and forming a passivation layer on all exposed surfaces of the etching mask and of the layer. The method continues by providing an etching gas at a second pressure; forming a second plasma from the etching gas; and etching, at an etch rate, the feature defined by the etching mask into the layer. The method further continues by providing a control valve such that the polymer deposition gas and the etching gas may be switched to within a selected time parameter, so that the first pressure and the second pressure are substantially equivalent and so that polymer deposition and substrate etching are repeated until a desired feature is achieved.

In some embodiments process pressures are maintained to within 10% of each other. In other embodiments, process pressures are substantially equivalent. In a preferred embodiment, the pressures range from 5 to 300 mTorr while in still other embodiments pressures are maintained at about 50 mTorr.

In some embodiments, a continuous plasma field is maintained. In still other embodiments, process gas switching occurs in less than about 250 milliseconds.

Another embodiment of the present invention provides a method for etching a feature in a layer through an etching mask where the method includes the steps of providing an etching gas at a first pressure; forming a first plasma from the etching gas; and etching, at an etch rate, the feature defined by the etching mask into the layer. The method continues by providing a polymer deposition gas at a second pressure; forming a second plasma from the polymer deposition gas; and forming a passivation layer on all exposed surfaces of the etching mask and of the layer. The method further continues by providing a control valve such that the etching gas and the polymer deposition gas may be switched to within a selected time parameter, so that the first pressure and the second pressure are substantially equivalent and so that substrate etching and polymer deposition are repeated until a desired feature is achieved.

In some embodiments process pressures are maintained to within 10% of each other. In other embodiments, process pressures are substantially equivalent. In a preferred embodiment, the pressures range from 5 to 300 mTorr while in still other embodiments pressures are maintained at about 50 mTorr.

In some embodiments, a continuous plasma field is maintained. In still other embodiments, process gas switching occurs in less than about 250 milliseconds.

### DESCRIPTION OF THE DRAWINGS

Embodiments of the invention may best be understood by reference to the following description taken in conjunction with the accompanying drawings in which:

FIGS. 1A-1C illustrate cross-sections of a conventional substrate etch having a mask material patterned on the substrate exhibiting isotropic and anisotropic etch properties;

FIG. 2 is a process flow chart for determining an optimized etch rate of a substrate in accordance with an embodiment of the present invention;

FIGS. 3A-3F illustrate cross-sections of a substrate etch in accordance with an embodiment of the present invention;

FIG. 4 is a process flow chart for optimally etching a substrate in accordance with an embodiment of the present invention; and

FIG. 5 is a schematic representation of an example apparatus that may be used in practicing embodiments of the present invention.

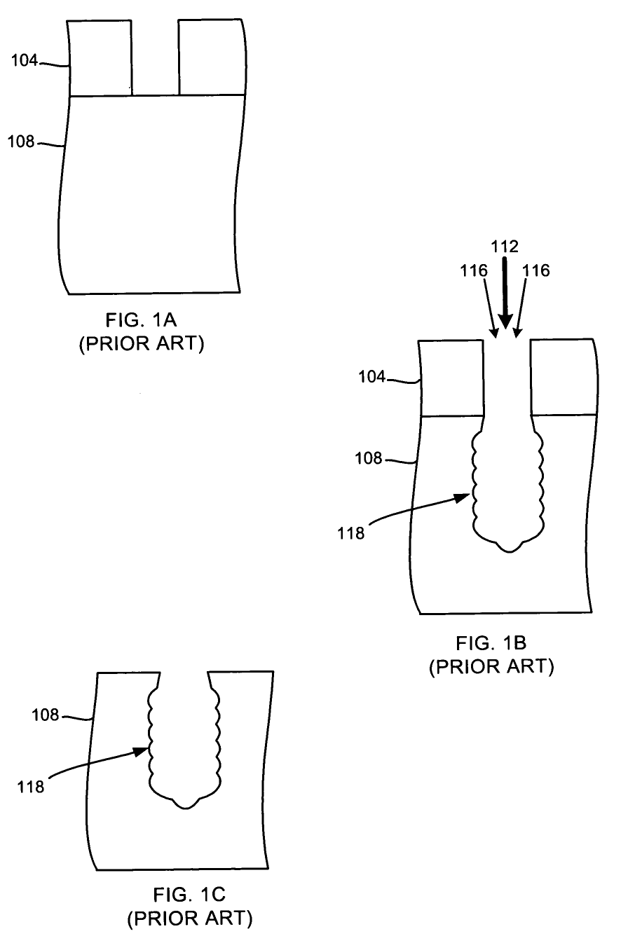

### DESCRIPTION OF THE INVENTION

The present method achieves advantages in sidewall profiles of etched substrates. In particular, scalloping is minimized during the etching of crystalline silicon substrate, epitaxial silicon, polysilicon, amorphous silicon, and other suitable layers.

Method: Determining Optimum Process Parameters

Generally speaking, an entire etch process may involve multiple cycles of deposition and etching sub-processes (e.g., dozens, hundreds, or more). It is believed that fast switching between deposition and etching sub-processes contribute to the absence or substantial reduction of scalloping in the resultant etch profile. Furthermore, it is believed that tailoring an entire etch process such that the chamber pressures during etch sub-processes and deposition sub-processes are substantially the same or as close as possible significantly contributes to the absence or substantial reduction of scalloping in the resultant etch profile.

In the following examples, a TCP9400® PTX plasma processing type system from Lam Research Corporation of Fremont, Calif. is employed. The present invention contemplates the use of compatible apparatuses to achieve the foregoing methods. The method described herein provides satisfactory etching in a silicon layer on a substrate while maintaining a relatively high throughput and low cost of ownership.

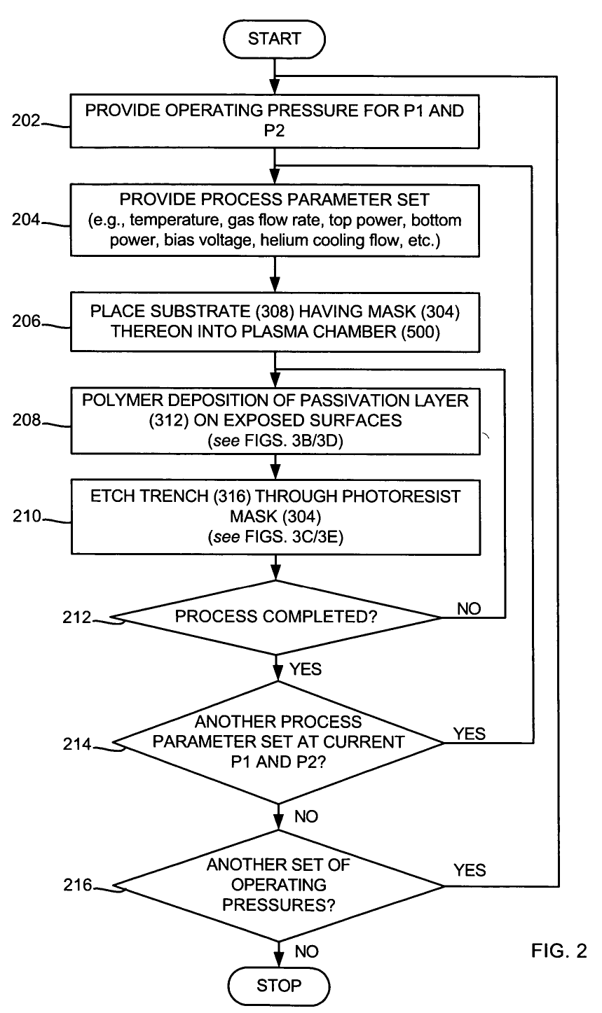

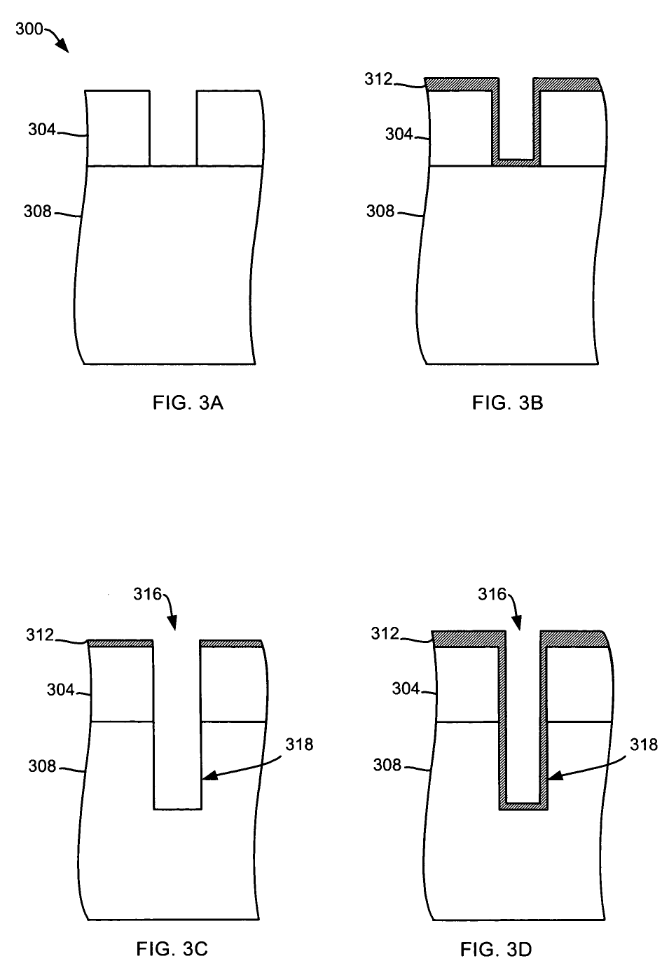

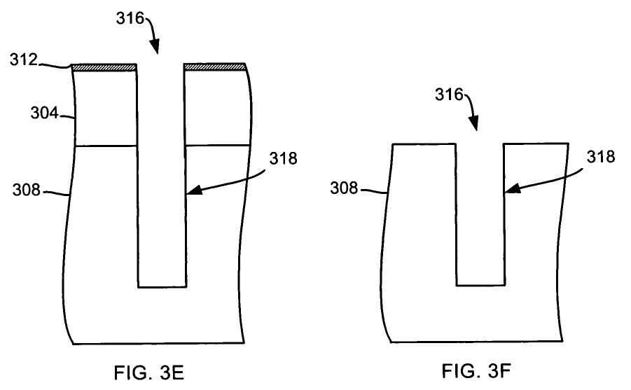

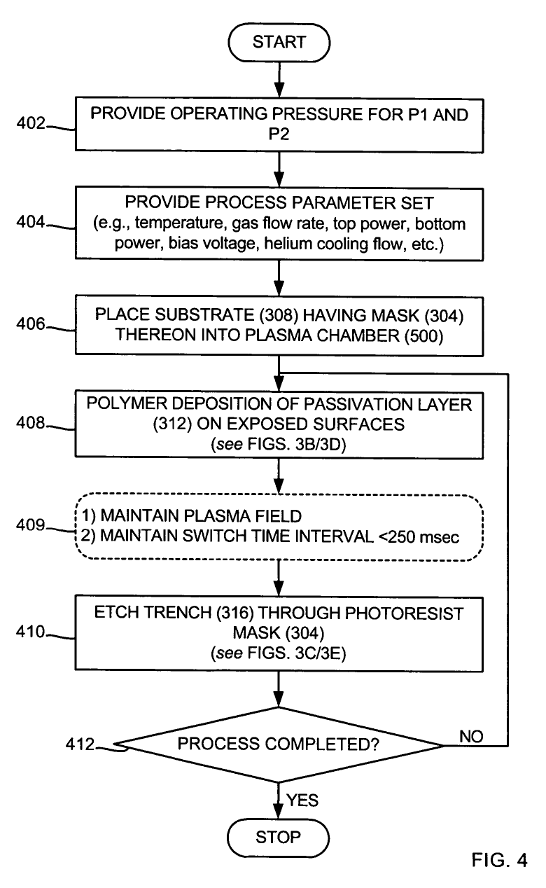

Referring to FIG. 2, FIG. 2 is an example process flow chart for determining an optimized etch rate of a substrate in accordance with an embodiment of the present invention. Note that FIGS. 3A-3F, which illustrate cross-sections of a substrate etch in accordance with an embodiment of the present invention will be discussed in combination with FIG. 2. Thus, in accordance with FIG. 2, at least one wafer 300 comprising a photo resist mask 304 and a substrate 308 may be processed to determine optimal control parameters in the factory environment for polymer deposition sub-processes and etch sub-processes that not only satisfy traditional requirements (e.g., a satisfactory etch with lowest cost of ownership) but also provide for polymer deposition sub-process pressures and etch sub-process pressures that are close to one another (preferably as close as possible and most preferably substantially the same). While the additional requirement that polymer deposition sub-process pressures and the etch sub-process pressures be close to one another may result in some compromise elsewhere, it is believed that such an approach is still worthwhile, in an embodiment, in that such approach may result in a highly advantageous etch profile, particularly with respect to the ability to avoid scalloping for deep etches or etches that involve narrow features.

While not wishing to be bound by theory, it is believed that a pressure differential between sub-processes may often result in a negative temporal factor that can reduce overall process rate because of the time required to equilibrate each process state. Furthermore, pressure differentials between sub-processes may cause the etch profile to become less anisotropic, which is generally undesirable.

As such, an operating pressure for P1 and P2 is provided at step 202. Pressure P1 represents a pressure at which polymer deposition of passivation layer may occur (see step 208). In like manner, P2 represents a pressure at which etching may occur (see step 210). Notably, in all embodiments, operating pressures of P1 and P2 are substantially the same. That is, in one embodiment, pressures P1 and P2 are within 10% of each other. In another embodiment, pressures P1 and P2 are within 5% of each other. In yet another embodiment, pressures P1 and P2 are within 2% of each other. In still another embodiment, pressures P1 and P2 are within 1% of each other. In other embodiments, pressures P1 and P2 are substantially equal. Furthermore, any number of operating pressures may be utilized so long as at any given operating pressure, P1 and P2 are substantially the same. Therefore, operating pressure may range from a few millitorr (mTorr) to a few hundred mTorr.

After an operating pressure for P1 and P2 is selected at a step 202, a process parameter set is provided at a step 204. Process engineers typically employ different combinations of process parameters in the factory environment to obtain a recipe that provides a satisfactory result (e.g., etch profile as specified by the device manufacturer, for example) while minimizing the cost-of-ownership for the tool owner (i.e., the entity that owns and/or operates the plasma processing equipment). Typically, this process involves selecting an etch recipe within a process window within which process parameters (temperature, gas flow rate, top power, bottom power, bias voltage, helium cooling flow rate, etc) may be varied in a factory environment to provide a satisfactory etch while requiring as little as possible by way of processing time, maintenance/cleaning burden, tool damage, and the like. Likewise, polymer deposition sub-processes may be practiced within a process window within which process parameters (temperature, gas flow rate, top power, bottom power, bias voltage, helium cooling flow rate, etc) may be varied to provide a satisfactory etch.

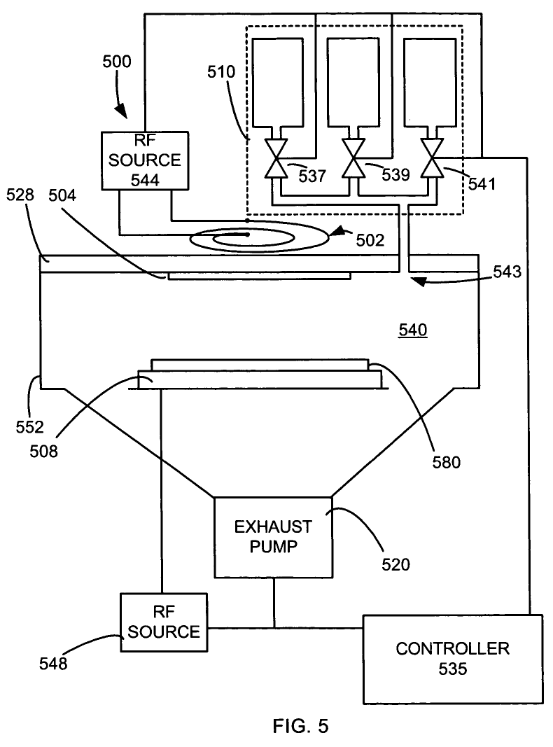

Once operating parameters are established, a wafer 300 (FIG.3) comprising a substrate 308 having a mask 304 thereon is placed into a plasma chamber 500 (FIG. 5) at a step 206. As noted above any number of substrates known in the art may be utilized including for example, silicon, polysilicon, or amorphous silicon films. Further, any number of masks well known in the art may be utilized including, for example, hard masks, resist masks, or oxide masks without departing from the present invention. A purpose of a mask is to create a barrier to the ion streams created in a process chamber. Masks allows for selective etching of an underlying substrate. FIG. 3A illustrates a cross-sectional portion of a wafer 300 comprised of a substrate 308 and mask 304 that is placed in a process chamber 500 (FIG. 5) at a step 204.

An example process chamber 500 is illustrated in FIG. 5 and will be discussed in further detail below. For purposes of this discussion, a process chamber 500 comprises a single chamber although one skilled in the art will recognized that the system may be a single chamber or a multi-chamber design. Wafer 300 may be secured in process chamber 500 in any manner well known in the art including, for example, a vacuum assisted chuck and/or an electrostatic chuck. In one example embodiment, wafer 300 is placed on the surface of bottom electrode with backside helium gas acting as a heat transfer media. Cooling may be achieved by means of a re-circulating chiller which maintains temperature above the condensation point. Typically, a set temperature may be about 15° C. Wafer 300 is cooled so as not to inhibit a polymer deposition step.

The following two steps (208/210) represent a cyclic process defined by polymer deposition (sub-process) resulting in a passivation layer alternating with etching (sub-process) a substrate. The process described herein is not limited by any order of steps 208-210 At a step 208, polymer deposition (sub-process) using, for example, Octofluorocyclobutane (C₄F₈) is illustrated in FIGS. 3B and 3D. C₄F₈ gas flow may be set from 30 standard cubic centimeters per minute (sccm) up to 200 sccm for polymer deposition steps. An initial polymer deposition pressure of C₄F₈ gas is established and gas flow rate is controlled by a throttle valve having a preset valve position. As seen in FIG. 3B, passivation layer 312 forms on the exposed surfaces of both mask 304 and substrate 308 layers. FIG. 3D illustrates a passivation layer 312 formed on sidewalls 318 of etch channel 316 subsequent to an etching step. One purpose of the passivation layer 312 is to provide protection for mask 304 and for sidewall 318 during an etching step.

A result of an etch step 210, is illustrated in FIGS. 3C and 3E. Silicon etch step (sub-process) using Sulfurhexafluoride (SF₆) may be performed before or after a deposition step (sub-process). SF₆ gas flow may be set from 30 sccm up to 300 sccm for an etching step. Initial etching pressure of SF₆ gas may be established and gas flow rate controlled by a throttle valve having a preset valve position (using a computerized control module). Note that deposition and etching process pressures may be set with the same preset valve position or with a different, but substantially similar preset valve position. Furthermore, a deposition and etching step overlap time can be set to begin after each cycle of preset deposition and etching time from a few seconds up to approximately 20 seconds. This overlap time may also be set with an individual step. FIG. 3C illustrates an etch channel 316 resulting from a cyclic etch step 210. Notably, a portion of the passivation layer 312 formed at step 208 is removed during etching. In preferred embodiments, a portion of passivation layer 312 that was formed on mask 304 during a polymer deposition step 208 remains on mask 304. As can be seen in FIG. 3C, mask 304 is protected from erosion by passivation layer 312 during a cyclic etching step 210. FIG. 3E illustrates a further etch step 210 in the cyclic process.

Once an etching step 210 has completed, the method determines whether more etching is required at step 212. This determination may be based on any number of user selected parameters including, for example, desired etch depth or may be responsive to any other endpoint technique. If more etching is required, the process returns to step 208 and continues cycling until etching is no longer required. In this example, a plasma field generated for both deposition and etching steps is maintained throughout deposition and etching steps. Further, in some embodiments, gas switching between deposition and etching steps may be controlled by a mass flow control valve (MFC valve). A switch time interval between the two steps is preferably less than 250 milliseconds. An MFC valve simultaneously controls the gases corresponding to the two cycling steps such that, in some embodiments, only one gas is supplied to the process chamber at a time.

The process terminates at step 212 where the method then determines whether another processing parameter set should be investigated for the current pressures P1 and P2. If another processing parameter set is desired, the method returns to step 204 to provide a new processing parameter set (while maintaining the current pressures P1 and P2) whereupon the method continues through the steps described above. In one embodiment, a wafer having substantially identical configuration and composition may be placed in the chamber. In this manner, process profiles may be recorded and analyzed to determine an optimal process parameter set. In other embodiments, wafers having different compositions and/or configurations may be placed in the chamber using the same or different process parameter sets. Once all process parameter sets have been utilized, the method then proceeds to step 216 where it is determined whether another set of operating pressures P1 and P2 should be investigated. As noted above, process pressures P1 and P2 are substantially similar, but may range from a few mTorr to several hundred mTorr. The method then ends.

Thus, for example, a method for determining an optimal etch for a given wafer composition may outlined as follows:
1. P1=50 mTorr, where P2 is substantially equal to P1
   a. Process Parameter Set 1.1
      i. Deposition/Etch Cycle
   b. Process Parameter Set 1.2
      i. Deposition/Etch Cycle
   c. Process Parameter Set 1.3
      i. Deposition/Etch Cycle
2. P1=100 mTorr, where P2 is substantially equal to P1
   d. Process Parameter Set 2.1
      i. Deposition/Etch Cycle
   e. Process Parameter Set 2.2
      i. Deposition/Etch Cycle
   f. Process Parameter Set 2.3
      i. Deposition/Etch Cycle
3. P1=X mTorr, where P2 is substantially equal to P1
   g. Process Parameter Set 3.1
      i. Deposition/Etch Cycle

As can be seen from the above example, this iterative process may be continued indefinitely until all process parameter sets and all pressures are tested. The results will yield data that may be analyzed to determine the best etch process for given production criteria.

Method: Using Selected Process Parameters

Note that the sequence below is only illustrative for an exemplar etch using an exemplar recipe on an exemplar plasma processing system. Not all etch recipes will require all these steps. In other recipes, additional conventional steps may be employed.

The present invention contemplates several particular control parameters to optimize the etch rate, etch profile, and etch satisfaction. For example, chamber pressure throughout the deposition step and the etching step may be relatively maintained as close as possible. That is, for a given selected operating pressure, any difference between a deposition step operating pressure and an etching step operating pressure is preferably kept to a minimum. Maintaining a constant operating pressure throughout a deposition/etch cycle may reduce processing time because a system may not require wait intervals to equilibrate as in conventional systems. In an embodiment, deposition and etching process pressures are maintained at about 50 mTorr. An operating pressure range may be established from a few mTorr to several hundred mTorr.

Additionally, maintaining a plasma field during throughout deposition and etch steps, for example, may also be desirable. In order to maintain a plasma field, a system must remain as close to equilibrium as possible with respect to chamber pressure and gas volume. Maintaining a plasma field throughout a deposition/etch cycle may reduce processing time because a system may not require wait intervals to equilibrate as in conventional systems. The example presented herein utilizes a TCP (transformer coupled plasma) plasma source. However, other sources such as, ICP (inductive coupled plasma), ECR (Electron cyclotron resonance), RIE (reactive ion etching), and the like may be utilized without departing from the present invention.

Referring to FIG. 4, FIG. 4 is a process flow chart for optimally etching a substrate in accordance with an embodiment of the present invention. The process illustrated in FIG. 4 may be practiced in a production environment. In a step 402, an operating pressure for P1 and P2 is provided. Generally speaking, these process pressures are predetermined using, for example, the process illustrated in FIG. 2. For illustrative purposes, in an example embodiment, a pressure of 50 mTorr is set as noted above. Pressure is maintained by way of a controller 535 (FIG. 5). Controller 535 and its associated structures and finctions will be discussed in further detail below with respect to FIG. 5.

Process parameters are provided at step 404. Thus, for example, in an embodiment, C₄F₈ gas is used for deposition. Plasma from deposition gas is generated by subjecting the gas to a radio frequency of about 13.56 MHz from a top TCP plasma source and bottom electrodes. During deposition, TCP (top) power is maintained at about 400W and bias voltage is maintained at about 50V. SF₆ gas may be used for etching by releasing fluorine radicals by means of radio frequency of about 13.56 MHz from a top TCP plasma source and bottom electrodes. During etching, TCP (top) power is maintained at about 400W and bias voltage is maintained at about 100V. In some embodiments, argon gas is not introduced with both SF₆ and C₄F₈ gases during the etching and polymer deposition. As noted above, gas ionization in plasma state generally contains non-trivial amounts of incident ions present during plasma etching. These ions may strike a sidewall and remove a portion of a passivation layer or undercut a sidewall resulting in a scalloped profile. Therefore, duration time of each of deposition and etching steps may be maintained for less than about 12 seconds, in a preferred embodiment. Other process parameters may be set as determined by the optimization method described above.

An etch/deposition cycle 408/410 proceeds in a manner substantially similar to the etch/deposition cycle 208/210 as described above for FIG. 2. Thus, a result of a step 408, polymer deposition (sub-process) using, for example, C₄F₈ is illustrated in FIGS. 3B and 3D. C₄F₈ gas flow may be set from 30 sccm up to 200 sccm for a polymer deposition step. An initial polymer deposition pressure of C₄F₈ gas may be established where gas flow rate may be controlled by a throttle valve having a preset valve position. As seen in FIG. 3B, a passivation layer 312 forms on an exposed surfaces of both mask 304 and substrate 308 layers. FIG. 3D illustrates a passivation layer 312 formed on sidewalls 318 of an etch channel 316 subsequent to an etching step. One purpose of a passivation layer 312 is to provide protection to mask 304 and to sidewall 318 during an etching step.

A result of an etch step 410, is illustrated in FIGS. 3C and 3E. A silicon etch step (sub-process) using SF₆ may be performed before or after a deposition step (sub-process). SF₆ gas flow may be set from 30 sccm up to 300 sccm for an etching step. An initial etching pressure of SF₆ gas may be established where gas flow rate may be controlled by a throttle valve having a preset valve position (using controller 535). Note that deposition and etching process pressures can be set with the same preset valve position or with a different, but substantially similar, preset valve position. Furthermore, a deposition and etching step overlap time can be set to begin after each cycle of preset deposition and etching time from a few seconds up to approximately 20 seconds. This overlap time can also be set with an individual step. FIG. 3C illustrates an etch channel 316 resulting from an etch step 410. Notably, a portion of passivation layer 312 formed at a step 408 may be removed during etching. In preferred embodiments, a portion of passivation layer 312 that was formed on mask 304 during a polymer deposition step 408 remains on mask 304. As can be seen in FIG. 3C, mask 304 may be protected from erosion by passivation layer 312 during an etching step 410. FIG. 3E illustrates a further etch step 410 in a cyclic process.

In the described embodiment, maintaining a plasma field and a switch time interval throughout cycle 409 may be desirable. Maintaining a plasma field and a switch time interval between gases may contribute to stable equilibrium states, which, as mentioned above, may reduce processing time because a system may not require wait intervals to equilibrate as in conventional systems. As noted above, switch time intervals are preferably less than 250 milliseconds. In some embodiments a mass flow control valve may be utilized to switch between process gases. A single gas valve assures that only one type of gas is released into the plasma chamber 500 at a time. The method continues until the desired etch is achieved whereupon the method determines that additional processing is not required at step 412. The method then ends.

Apparatus

Referring to FIG. 5, FIG. 5 is a generalized schematic view of a process chamber 500 that may be used in an embodiment of the invention. In the embodiment illustrated, a plasma processing chamber 500 comprises transformer coil plasma (TCP) coils 502, an upper electrode 504, a lower electrode 508, a gas source 510, at least one RF source 548/544, an exhaust pump 520, and a controller 535. Chamber walls 552 define a plasma enclosure in which TCP coils 502, upper electrode 504, and lower electrode 508 are disposed. Electrodes 504/508 and TCP coils 502 define confined plasma volume 540. At least one RF source 548/544 is electrically connected with upper electrode 504 and the lower electrode 508. RF source 548/544 may comprise single or different combinations of RF to power upper electrode 504 and lower electrode 508 as noted above. Within plasma processing chamber 500, wafer 580, comprising a substrate layer and a mask layer, is positioned upon lower electrode 508. Lower electrode 508 incorporates a suitable substrate chucking mechanism (e.g., electrostatic, mechanical clamping, or the like) for holding wafer 580. Plasma reactor top 528 incorporates upper electrode 504 disposed immediately opposite lower electrode 508.

Gases may be supplied to confined plasma volume 540 by gases source 510 through a gas inlet 543 and may be exhausted from confined plasma volume 540 by exhaust pump 520. Gas source 510 further comprises a passivation layer gas source 512, an etchant gas source 514, and an additional gas source 516. Regulation of gas flow for the various gases is accomplished by valves 537, 539, and 541. In an alternate embodiment, the gas flow for the various gases may be accomplished by a single mass flow control valve (not shown). In other words, separate gases may be routed to a common multiport valve so that switching between gases may be controlled at a single process point by controller 535. Exhaust pump 520 forms a gas outlet for confined plasma volume 540.

Controller 535 may be electronically connected with various components of a system to regulate plasma process components including, for example, an RF source 544/548, an exhaust pump 520, a control valve 537 connected with a passivation layer gas source 512, a control valve 539 connected with an etchant gas source 514, and a control valve 541 connected with an additional gas source 516. As noted above, a single mass flow valve (not shown) may also be electronically connected with controller 535 so that switching between gases may be controlled at a single process point. Controller 535 may also be used to control: gas pressure in a wafer area; wafer backside He cooling pressure; bias; and various temperatures in synchronization with valve controls.

While this invention has been described in terms of several preferred embodiments, there are alterations, permutations, modifications and various substitute equivalents, which fall within the scope of this invention. For example, although an etch sub-step is shown preceding a deposition sub-step in FIGS. 2 and 4, these sub steps may be reversed if desired. It should also be noted that there are many alternative ways of implementing the methods and apparatuses of the present invention. It is therefore intended that the following appended claims be interpreted as including all such alterations, permutations, modifications, and various substitute equivalents as fall within the true spirit and scope of the present invention.

1. A method for etching a feature in a layer through an etching mask comprising:
a) providing a polymer deposition gas at a first pressure;
forming a first plasma from the polymer deposition gas;
forming a passivation layer on all exposed surfaces of the etching mask and of the layer;
b) providing an etching gas at a second pressure;
forming a second plasma from the etching gas;
etching the feature defined by the etching mask into the layer; and
c) providing a control valve for switching between the polymer deposition gas and the etching gas within a selected time parameter, wherein the first pressure and the second pressure are substantially equivalent and wherein the steps a) and b) are repeated until the feature is achieved.

2. The method as recited in claim 1 wherein the difference between the first pressure and the second pressure is less than 10%.

3. The method as recited in claim 1 wherein the first pressure and the second pressure are selected to optimize an etch rate in forming the feature.

4. The method as recited in claim 1 wherein the first pressure and the second pressure are maintained at about 3 mTorr to about 300 mTorr.

5. The method as recited in claim 1 wherein the first pressure and the second pressure are maintained at about 50 mTorr.

6. The method as recited in claim 1 wherein steps a) and b) temporally overlap such that a continuous plasma field is maintained.

7. The method as recited in claim 6 wherein the overlap is less than about 20 seconds in duration.

8. The method as recited in claim 1 wherein the selected time parameter is less than about 250 milliseconds.

9. The method as recited in claim 1 wherein depositing the passivation layer and etching the feature are performed in a common chamber.

10. The method as recited in claim 1 wherein the layer is a silicon based substrate.

11. A method for etching a feature in a layer through an etching mask comprising:
a) providing an etching gas at a first pressure;
forming a first plasma from the etching gas; and
etching a feature defined by the etching mask into the layer;
b) providing a polymer deposition gas at a second pressure;
forming a second plasma from the polymer deposition gas;
forming a passivation layer on all exposed surfaces of the etching mask and of the layer;
c) providing a control valve for switching between the polymer deposition gas and the etching gas within a selected time parameter, wherein the first pressure and the second pressure are substantially equivalent and wherein the steps a) and b) are repeated until the feature is achieved.

12. The method as recited in claim 11 wherein the difference between the first pressure and the second pressure is less than 10%.

13. The method as recited in claim 11 wherein the first pressure and the second pressure are selected to optimize an etch rate while forming the feature.

14. The method as recited in claim 11 wherein the first pressure and the second pressure are maintained at about 3 mTorr to about 300 mTorr.

15. The method as recited in claim 11 wherein the first pressure and the second pressure are maintained at about 50 mTorr.

16. The method as recited in claim 11 wherein steps a) and b) temporally overlap such that a continuous plasma field is maintained.

17. The method as recited in claim 16 wherein the overlap is less than about 20 seconds in duration.

18. The method as recited in claim 11 wherein the selected time parameter is less than about 250 milliseconds.

19. The method as recited in claim 11 wherein depositing the passivation layer and etching the feature are performed in a common chamber.

20. The method as recited in claim 11 wherein the layer is a silicon based substrate.
